(19) United States
(12) Patent Application Publication
(10) Pub. No.: US 2010/0230790 A1
(43) Pub. Date: Sep. 16, 2010

(54) Semiconductor Carrier for Multi-Chip Packaging

(75) Inventor: Donald Disney, Cupertino, CA (US)

Correspondence Address: ADVANCED ANALOGIC TECHNOLOGIES, 3230 Scott Blvd, Santa Clara, CA, 95054, US

(73) Assignee: ADVANCED ANALOGIC TECHNOLOGIES, INC., Santa Clara, CA (US)

(21) Appl. No.: 12/402,770

(22) Filed: Mar. 12, 2009

(51) Int. Cl. H01L 23/495

(52) U.S. Cl. 257/666; 257/690; 257/E23.031

(57) ABSTRACT

A power semiconductor product includes a carrier attached to a leadframe. An insulating layer is formed on the carrier and two or more conductive plates are patterned on the insulating layer. A control IC is attached to one of these conductive plates and a power transistor is attached to the other. Bond wires connect the first conductive plate to a pin on the leadframe. Additional bond wires attach the control IC to pins on the leadframe and form connections between the control IC and the power transistor.

### BACKGROUND OF THE INVENTION

Many power semiconductor products comprise a single package in which a plurality of individual semiconductor die are housed. By way of example, FIG. 1 shows the top-view of a prior art semiconductor product, including the outline of package 101, first leadframe 102, second leadframe 103, control IC 104, and power transistor 105. This configuration is often used for power semiconductor products that require one or more discrete power transistors to block high voltages and/or conduct high currents in a more efficient manner than could be achieved by integrating the power transistors monolithically with the control IC. In this example, package 101 completely encloses leadframes 102 and 103, electrically isolating them from the underlying circuit board (not shown). Electrical isolation between control IC 104 and power transistor 105 is provided by the separation of leadframes 102 and 103. This is an important feature, since the backside of power transistor 105 is typically the drain terminal of this device and, as such, is subject to high voltages and possibly fast, high-voltage excursions. Electrical contact to the drain terminal (backside) of power transistor 105 is made via lead 107 and conductive epoxy (not shown).

Because power transistor 105 may conduct high currents and/or switch high voltages, it may dissipate a significant amount of heat during normal operation. Control IC 104 may also dissipate a significant amount of heat. Therefore, a key criterion for the semiconductor package is to provide a good path for heat to be conducted away from the semiconductor devices, so that their temperatures remain in a safe operating range (e.g. below 150 C). The semiconductor die 104 and 105 are typically attached to the package leadframes 102 and 103 by a material that offers reasonably good thermal conduction, such as silver-filled epoxy or eutectic solder. The thermal conduction path from the leadframes to the circuit board on which the package is mounted (not shown in FIG. 1) is sometimes provided by the leads themselves, as shown in FIG. 1, in which lead 106 conducts heat from IC 104 via leadframe 102, while leads 107 and 108 conduct heat from power transistor 105 via leadframe 103.

FIG. 2 shows the top-view of an alternative prior art implementation. Unlike FIG. 1, this implementation includes a single leadframe, and package 201 does not cover the backside of the leadframe, such that the leadframe is exposed on the bottom and can thus be soldered or otherwise attached to the underlying circuit board (not shown). This exposed leadframe typically provides a much lower thermal resistance than is possible using the leads, as in the example of FIG. 1. However, since control IC 204 and power transistor 205 are both attached to the same leadframe 202, there is a need to provide electrical isolation between these two semiconductor die. Because power transistor 205 typically dissipates more heat than control IC 204, power transistor 204 is typically attached to leadframe 202 by a material that offers reasonably good thermal conduction, such as silver-filled epoxy or eutectic solder. Electrical contact to the drain terminal (backside) of power transistor 205 is made via lead 207, bond wires 208, leadframe 202, and conductive epoxy (not shown).

The prior art example of FIG. 2 has several disadvantages. To provide electrical isolation, control IC 204 is typically attached to leadframe 202 with an insulating epoxy, which generally has much worse thermal conduction compared to conductive die attach materials. Another disadvantage of this approach is that the voltage on leadframe 202 is the same as the voltage on the backside of power transistor 205. As described above, this node is often subject to high voltages and may also experience fast switching transients from low-to-high and high-to-low voltage. Having a high-voltage exposed leadframe often creates problems on the circuit board to which it is attached. First, the heatsink (usually a large copper trace on the circuit board) that is attached to the leadframe is at high-voltage, while it is preferable for this heatsink to be biased at ground potential. Second, if the leadframe and heatsink are subject to fast, high-voltage transients, they often become a source of electro-magnetic interference (EMI).

Objectives of this invention are to provide a method and apparatus for providing co-packaged power semiconductor products that overcome the limitations of the prior art, including the use of non-conductive epoxy and exposed high-voltage leadframes.

### SUMMARY OF THE INVENTION

A typical embodiment of the present invention includes a control IC and a power transistor co-packaged in a single package. The package also includes a single leadframe that is preferably exposed on the backside for better thermal conduction. A carrier is attached to the leadframe, preferably by a method that provides good thermal conductivity, such as conductive epoxy or eutectic solder. The carrier is preferably made from semiconductor material, such as silicon, which provides good thermal conduction.

The top surface of the carrier includes one or more conductive plates on which the semiconductor die are mounted. In this example, the control IC is attached to one such conductive plate and the power transistor is attached to another. These attachments are preferably made using a conductive material, such as conductive epoxy. Electrical connections between the semiconductor die and package pins are made using bond wires. Thus, for the example being described bond wires are typically used to connect the source and drain of the power transistor to respective pins. Bond wires can also be used to form electrical connections between the semiconductor die. So, for this example it would be typical to provide a bond wire connecting the control IC to the gate of the power IC.

### BRIEF DESCRIPTION OF THE DRAWINGS

FIG. 1 is a top-view of a prior art co-packaged power semiconductor product with a separate leadframe for each semiconductor die.

FIG. 2 is a top-view of a prior art co-packaged power semiconductor product with a common leadframe for all of the semiconductor die.

FIG. 3 is a top-view of one embodiment of the present invention.

FIG. 4 is a schematic is a cross-section view of one embodiment of the present invention.

FIG. 5 is a top-view of one embodiment of the present invention.

FIG. 6 is a top-view of one embodiment of the present invention.

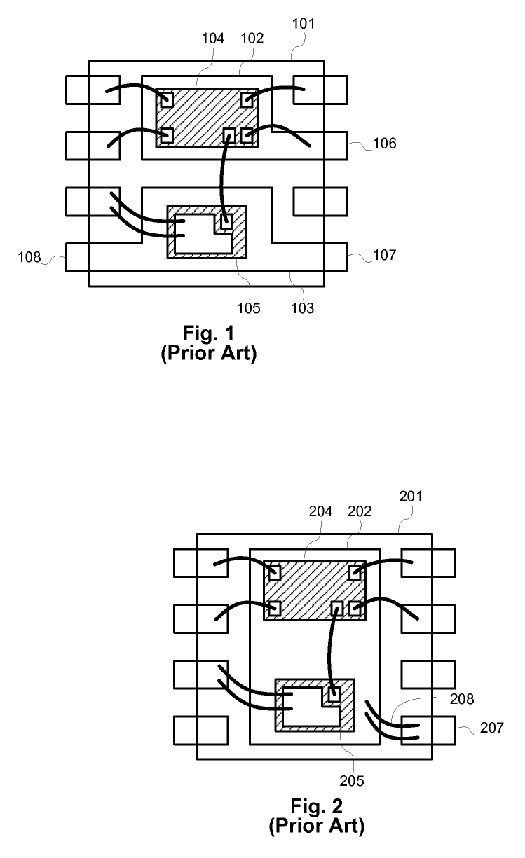

### DETAILED DESCRIPTION OF THE PREFERRED EMBODIMENTS

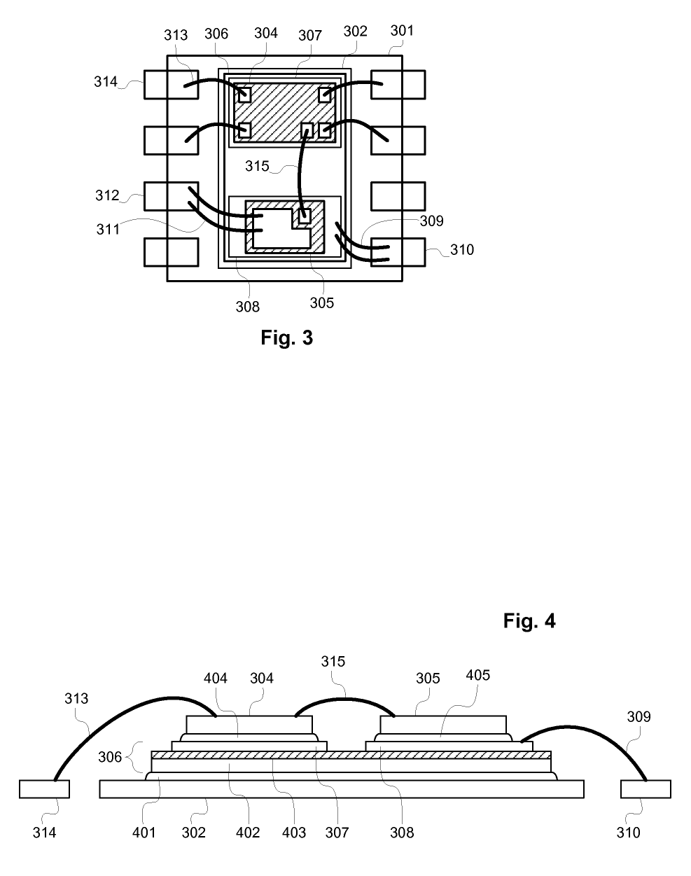

FIG. 3 shows a top-view of an improved power semiconductor product that comprises a control IC 304 and a power transistor 305 co-packaged in a package 301. Package 301 includes a single leadframe 302 that, in a preferred embodiment, is exposed on the backside for better thermal conduction, as described above. A carrier 306 is attached to leadframe 302, preferably by a method that provides good thermal conductivity, such as conductive epoxy or eutectic solder. Carrier 306 preferably comprises a semiconductor material, such as silicon, which also provides good thermal conduction. The top surface of carrier 306 comprises one or more conductive plates on which the semiconductor die are mounted. In this example, control IC 304 is attached to conductive plate 307 and power transistor 305 is attached to conductive plate 308. These attachments are preferably made using a conductive material, such as conductive epoxy. Electrical contact to the backside (e.g. the drain terminal) of power transistor 305 is provided from pin 310 through bond wires 309 which are attached to conductive plate 308. Bond wires 311 connect the topside (e.g. the source terminal) of power transistor 305 to pin 312. Other bond wires connect the bond pads of control IC 304 to other pins, shown by example as bond wire 313 connected to pin 314. Bond wires may also be made directly between the co-packaged semiconductor die. For example, bond wire 315 connects a bond pad on control IC 304 to a bond pad (e.g. the gate terminal) of power transistor 305.

FIG. 4 shows a schematic cross-section of the power semiconductor product of FIG. 3. Control IC 304 is attached to conductive plate 307 of carrier 306 by conductive epoxy 404. Power transistor 305 is attached to conductive plate 308 of carrier 306 by conductive epoxy 405. Carrier 306 comprises a semiconductor substrate 402, insulating layer 403, and a patterned metallization layer that forms conductive plates 307 and 308. Carrier 306 is attached to package leadframe 302 by conductive epoxy 401. Pin 310 is electrically connected to conductive plate 308 by bondwire 309. Bondwire 315 connects bond pads on the topsides of control IC 304 and power transistor 305. Bondwire 313 connects another bond pad on control IC 304 to pin 314.

Carrier 306 is preferably fabricated using inexpensive semiconductor processing steps. Because there are no active devices formed in substrate 402, it is possible to use a low grade of semiconductor starting material, such as reclaimed single-crystal silicon wafers or even polysilicon wafers. Substrate 306 should be as thin as possible to minimize its thermal resistance, within the limits of thickness requirements for high-yield manufacturing. A thinner substrate will also reduce the total height of the stacked die/carrier, which will allow for the use of thinner packages. For example, a final carrier thickness of 100-200 um may be used.

Insulating layer 403 is optional and serves, in a preferred embodiment, to electrically isolate patterned conductive plates 307 and 308 from each other and from substrate 402. It is preferable for insulating layer 403 to have good thermal conductivity, to allow better heat removal from control IC 304 and power transistor 305. Insulating layer 403 may comprise, for example, thermally grown and/or deposited silicon dioxide, silicon nitride, spin-on-glass, or other common materials used in semiconductor fabrication. The thickness of this layer is preferably thick enough to support the voltage between the backside of power transistor 305 and the grounded leadframe 302, but as thin as possible to minimize the thermal resistance of this layer. By way of example, a 100 nm thick silicon dioxide film may be used to provide adequate electrical isolation for power transistors with operating voltages below 100V, while introducing a fairly small thermal resistance.

One of the main advantages of this invention is that a low-cost carrier is made from an inexpensive semiconductor substrate with minimal, low-cost fabrication processes. An entire semiconductor wafer may be fabricated for very low cost and then diced into hundreds or thousands of individual carriers. The pattern of the conductive plates on each carrier may be transferred to each die using low-cost photolithography. Since the feature sizes are so large, it is possible to use inexpensive contact printing. The carrier provides electrical isolation between the semiconductor die and the package leadframe, such that the leadframe may be grounded on the circuit board to which it is mounted. Moreover, the carrier also provides electrical isolation among the die that are mounted on top of it, obviating the need for a more expensive package with multiple leadframes. Thus, this invention provides greater flexibility and lower cost than prior art solutions.

Conductive plates 307 and 308 are preferably patterned from a conductive metallization layer. Again, it is preferable to use inexpensive semiconductor processing steps. The sheet resistance of conductive plate 308 should be low because the resistance of this layer is electrically in series with the main current path through power transistor 305. In a preferred embodiment, a single layer of aluminum, copper, or aluminum/copper alloy with a thickness of 3 um-20 um may be used. Two other requirements for this metallization layer are the ability to form reliable wire bonds to it and the ability to form a reliable connection to the material that attaches the power transistor to it. In one embodiment, each of these requirements is independently optimized by using a first metallization layer that is exposed in the wire bonding area and a second metallization layer that is exposed in the area used for attachment of the overlying semiconductor die. For example, a layer of aluminum may be patterned into conductive plates 307 and 308, and then a copper or nickel-plating process may be used to coat the aluminum with one of these other materials, but only in the areas to be used for die attachment. This way the exposed aluminum may be used for wire bonding, while the exposed copper or nickel is used for adhesion of the conductive epoxy.

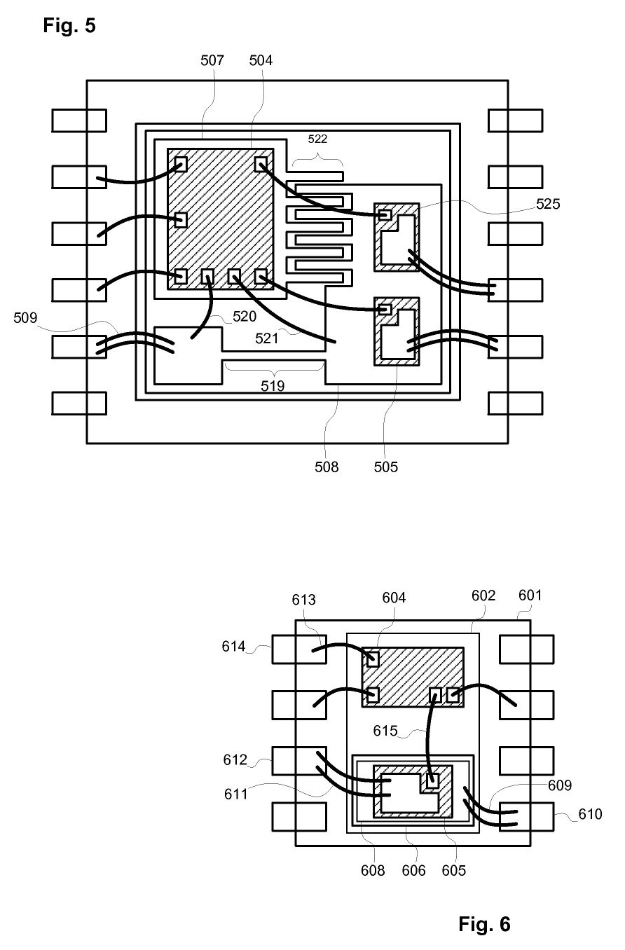

FIG. 5 shows an alternate embodiment of this invention, in which the metallization layer is patterned to provide some additional functionality. For example, the conductive plate 508 is patterned to introduce a metal resistor 519 between the backside of power device 505 and bond wires 509. The power device current flowing through metal resistor 519 will develop a voltage drop, and this voltage drop may be measured via bond wires 520 and 521 placed on each side of metal resistor 519 and connected to the control IC 504, in order to monitor the current flow through power device 505. In another feature shown in FIG. 5, conductive plate 508 is extended under a plurality of semiconductor die (power transistors 505 and 525 in this example), such that the conductive plate provides an electrical connection between the backsides of all of these die, eliminating the need for connection external to the package. In a third feature of FIG. 5, conductive plates 507 and 508 are patterned in an interdigitated (i.e. comb-like) manner to increase their overlap area and provide a capacitor 522 between these two plates.

FIG. 6 shows another embodiment of this invention, similar in most aspects to the example of FIG. 3, except that carrier 606 is placed only under power transistor 605. Package 601 includes a single leadframe 602 Carrier 606 is attached to leadframe 602, preferably by a conductive material. The top surface of carrier 606 comprises one conductive plate 608 on which power transistor 605 is mounted. In this example, control IC 604 is attached directly to leadframe 602, preferably by a conductive material, such as conductive epoxy. Having one semiconductor die mounted directly to the leadframe reduces the thermal resistance compared to the configuration of FIG. 3. Electrical contact to the backside (e.g. the drain terminal) of power transistor 605 is provided from pin 610 through bond wires 609 which are attached to conductive plate 608 formed on carrier 606. Bond wires 611 connect the topside of power transistor 605 to pin 612. Other bond wires connect the bond pads of control IC 604 to other pins, shown by example as bond wire 613 connected to pin 614. Bond wires may also be made directly between the co-packaged semiconductor die. For example, bond wire 615 connects a bond pad on control IC 604 to a bond pad of power transistor 605.

In further embodiments of this invention, electrical devices may be fabricated in the semiconductor carrier to provide further functionality at relatively low incremental cost. For example, diffused resistors and diodes may be formed by adding only two mask steps to the fabrication of the semiconductor carrier (e.g. one masked implantation and one contact mask to form a contact hole through the insulating layer). The resistors and diodes can be used to provide, for example, current sensing and temperature sensing functions.

Variations of the specific details outlined above are well within the scope of this invention. For example, it may be preferable in some applications to pattern the insulating layer 403, rather than having it cover the entire substrate 402. In this way, certain conductive plates may be in direct electrical contact with substrate 402. A control IC with a grounded substrate may benefit from the removal of this insulating layer for enhanced electrical and thermal conduction. While the preceding examples have shown only two or three semiconductor die co-packaged on a single carrier, it is easy to co-package a greater number of semiconductor die by patterning additional conductive plates on the carrier.

What is claimed is:

1. A semiconductor product that comprises:
a package comprising a leadframe;
a carrier attached to the leadframe;
an insulating layer formed on the carrier;
first and second conductive plates formed on the insulating layer;
a first semiconductor die attached to the first conductive plate;
a second semiconductor die attached to the second conductive plate to form an electrical connection between the conductive plate and the second semiconductor die;
a first bond wire connecting the second conductive plate to a first pin of the package; and
a second bond wire connecting the first semiconductor die to a second pin of the package.

2. A semiconductor product as recited in claim 1 wherein the carrier comprises:
a semiconductor substrate;
an insulating layer disposed on the substrate; and
a conductive layer patterned onto the insulating layer to form the first and second conductive plates.

3. A semiconductor product as recited in claim 2 wherein the conductive layer further comprises:
a first metallization layer patterned onto the insulating layer where the metallization conductive layer is composed of a material suitable for wire bonding;
a second metallization layer patterned onto a portion of the first conductive layer that corresponds to the location of the second semiconductor die, where the second metallization layer is composed of a material that suitable for providing a low resistance contact to the second semiconductor die

4. A semiconductor product as recited in claim 3 wherein the first metallization conductive layer is composed of copper, aluminum or copper aluminum alloy and where the second metallization layer is composed of copper or nickel.

5. A power semiconductor as recited in claim 1 wherein an electrically conductive material is used to bond the carrier to the leadframe, the first semiconductor die to the first conductive plate, and the second semiconductor die to the second conductive plate.

6. A power semiconductor product that comprises:
a package comprising a leadframe;
a carrier attached to the leadframe;
an insulating layer formed on the leadframe;
a first conductive plate attached to the carrier;
a second conductive plate attached to the insulating layer;
a control IC attached to the first conductive plate;
a power transistor attached to the second conductive plate to form an electrical connection between the second conductive plate and the power transistor;
a bond wire connecting the second conductive plate to a first pin of the package; and
a bond wire connecting the control IC to a second pin of the package.

7. A power semiconductor as recited in claim 6 wherein the carrier comprises:
a semiconductor substrate;
an insulating layer disposed on a portion of the substrate; and
a conductive layer patterned onto the insulating layer and the substrate to form the first and second conductive plates.

8. A power semiconductor as recited in claim 7 wherein the conductive layer comprises:
a first metallization layer composed of a material suitable for wire bonding;
a second metallization layer patterned onto a portion of the first metallization layer that corresponds to the location of the power transistor, where the second metallization layer is composed of a material suitable for providing a low resistance contact to the power transistor.

9. A power semiconductor as recited in claim 8 wherein the metallization conductive layer is composed of copper, aluminum or copper aluminum alloy and where the second metallization layer is composed of copper or nickel.

10. A power semiconductor as recited in claim 6 wherein an electrically conductive material is used to bond the carrier to the leadframe, the control IC to the first conductive plate, and the power transistor to the second conductive plate.

11. A power semiconductor as recited in claim 1 wherein the first semiconductor die is an integrated circuit and the second semiconductor die is a power transistor.

12. A power semiconductor as recited in claim 1 wherein a bottom surface of the leadframe is not encapsulated by the package.

13. A power semiconductor as recited in claim 1, the second conductive plate further comprising a resistive portion between the second semiconductor die and the first bond wire

14. A power semiconductor as recited in claim 1 further comprising a third semiconductor die attached to the first conductive plate

15. A power semiconductor as recited in claim 1 further comprising a third semiconductor die attached to the second conductive plate

16. A power semiconductor as recited in claim 1 wherein the first and second conductive plates are interdigitated to provide increased electrical capacitance between the first and second conductive plate

17. A power semiconductor as recited in claim 1 wherein the carrier is thermally conductive, the carrier is attached to the leadframe by a thermally conductive material, the first semiconductor die is attached to the first conductive plate by a thermally conductive material, and the second semiconductor die is attached to the second conductive plate by a thermally conductive material.

18. A power semiconductor as recited in claim 1, the carrier comprising a semiconductor substrate, a diode formed in the semiconductor substrate.

19. A power semiconductor as recited in claim 18 further comprising a third conductive plate contacting one side of the diode, the diode providing a temperature sensing function.

20. A power semiconductor as recited in claim 1, the carrier comprising a semiconductor substrate, a resistor formed in the semiconductor substrate.

21. A power semiconductor as recited in claim 19 further comprising a third conductive plate contacting one side of the resistor, the resistor providing a current sensing function.

22. A power semiconductor product that comprises:
a package comprising a leadframe;
a carrier attached to the leadframe by a thermally conductive material;
an insulating layer formed on the carrier;
first and second conductive plates formed on the insulating layer, the first and second conductive plates being electrically isolated from each other;
a control IC attached to the first conductive plate by a thermally conductive material;
a power transistor attached to the second conductive plate by a thermally and electrically conductive material to form an electrical connection between the conductive plate and the second semiconductor die;
a first bond wire connecting the second conductive plate to a first pin of the package; and
a second bond wire connecting the control IC to a second pin of the package.

23. A power semiconductor product as recited in claim 22 further comprising a third bond wire connecting the control IC to the power transistor.

24. A power semiconductor product as recited in claim 23 further comprising a fourth bond wire connecting the power transistor to a third pin of the package.
